(19) United States
(12) Patent Application Publication
(10) Pub. No.: US 2003/0098495 A1
(43) Pub. Date: May 29, 2003

(54) Semiconductor device

(76) Inventors: Atsushi Amo, Tokyo (JP); Shunji Kubo, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/155,114

(22) Filed: May 28, 2002

(30) Foreign Application Priority Data
Nov. 29, 2001 (JP) 2001-364919

(51) Int. Cl. H01L 27/10; H01L 29/00

(52) U.S. Cl. 257/530; 257/529; 257/209

(57) ABSTRACT

The present invention provides a semiconductor device comprising: antifuses having insulation films; and a breakdown-circuit transistor provided in a breakdown circuit for breaking down the insulation films to set the antifuses in a conductive state. The insulation films of the antifuses are made up of the same material as that for a gate insulation film of the breakdown-circuit transistor and formed such that the film thickness of the insulation films are thinner than that of the gate insulation film.

### BACKGROUND OF THE INVENTION

1. Field of the Invention

The present invention relates to a semiconductor device having antifuses therein.

2. Background Art

Conventionally, many of semiconductor devices such as DRAMs and SRAMs have blowable fuses therein as elements. These semiconductor devices include the fuses in a replacement circuit for replacing memory cells or a reference voltage generation circuit for adjusting a reference voltage.

Such a conventional semiconductor device will be briefly described below with reference to FIGS. 8 and 9.

FIG. 8 is a circuit diagram showing a replacement circuit for replacing memory cells by use of fuses in the conventional semiconductor device. FIG. 9 is a schematic diagram showing fuses provided in the replacement circuit shown in FIG. 8.

The replacement circuit shown in FIG. 8 is provided to increase the yield of the semiconductor device as a product. Specifically, the replacement circuit replaces defective memory cells with reserve memory cells (redundant cells) incorporated in the device. The defective memory cells to be replaced include those which have become defective due to mixing of a foreign object into them in the fabrication process and those for DRAMs whose refresh characteristics do not satisfy their specification.

In FIG. 8, reference numerals G11 and G22 denote inverters; V a source potential; RE a resistance; L₀ to L₂ₘ₊₁ fuse portions; TA and T₀ to T₂ₘ₊₁ transistors; S a select signal; and R₀ to Rₘ and /R₀ to /Rₘ address signals.

In the circuit of FIG. 8 configured as described above, when the output on a terminal (or node) NAE (Normal Address Enable) is at the HIGH level, the output on a terminal (node) SAE (Spare Address Enable) is at the LOW level since the output on the terminal NAE is inverted by the inverter G22. In this state, the address signals R₀ and /R₀, . . . , and Rₘ and /Rₘ specified from outside the device are transferred to a memory cell in the device as they are. At that time, no redundant cell in the device is selected.

When the output on the terminal NAE is at the LOW level, on the other hand, the output on the terminal SAE is at the HIGH level. In this state, the address signals R₀ and /R₀, . . . , and Rₘ and /Rₘ specified from outside the device are not transferred to a memory cell in the device and a redundant cell in the device is selected instead.

A specific example will be described below. For example, assume that an address corresponding to a defective cell is set so that R₀=0, . . . , Rᵢ=0, . . . , Rₘ=0.

At that time, the complementary address is such that /R₀=1, . . . , /R₁=1, . . . , /Rₘ=1. The fuse portions for these address signals are controlled by a program in such a way that the even number fuse portions L₀, . . . , L₂ᵢ, . . . , L₂ₘ are conductive whereas the odd number fuse portions L1, . . . . L₂ᵢ+1, . . . , L₂ₘ+1 are not conductive.

The memory cell replacement operation will be described below. When the select signal S is entered, thereby setting the terminal at the HIGH level, the transistor TA is turned on, making the potential of the node N1 equal to the source potential V. After that, the address signals R₀ and /R₀, . . . , and Rₘ and /Rₘ are input to the gate portions of the transistors T₀, . . . , T₂ₘ₊₁, respectively.

In this state, when the address (R₀=0, . . . , Rᵢ=0, . . . , Rₘ=0) corresponding to the above defective cell is selected, each portion of the complementary address (/R₀=1, . . . , /Rᵢ=1, . . . , Rₘ=1) is input to the gate portion of a respective one of the odd number transistors T₁, . . . , T₂₁₊₁, . . . , T₂ₘ₊₁, thereby turning on these transistors. At that time, the odd number fuse portions L₁, . . . , L₂ᵢ₊₁, . . . , L₂ₘ₊₁ are controlled so that they are not conductive.

The even number fuse portions L₀, . . . , L₂ᵢ, . . . , L₂ₘ, on the other hand, are controlled so as to be conductive. However, the address signals are not input to the gate portions of the corresponding even number transistors T₀, . . . , T₂ᵢ, . . . , T₂ₘ, thereby turning off these transistors.

As a result, the potential V of the node N1 is not grounded to the ground GND and therefore remains at the HIGH level. The potential V of the node N1 is inverted by the inverter G11 to set the output on the terminal NAE at the LOW level. Furthermore, the output on the terminal NAE is inverted by the inverter G22 to set the output on the terminal SAE at the HIGH level, thereby selecting a redundant cell as described above.

When an address other than the defective address (R₀=0, . . . , Rᵢ=0, . . . , Rₘ=0) is selected, on the other hand, at least one of the address signals R₀ to Rₘ is set at the HIGH level, turning on the corresponding transistor. For example, if an address signal is applied such that Rᵢ=1, the corresponding transistor T₂ᵢ is turned on. At that time, since the corresponding fuse portion L₂ᵢ is controlled so as to be conductive, the node N1 is grounded, setting the output on the terminal NAE at the HIGH level and thereby the output on the terminal SAE at the LOW level, and, as a result, the redundant memory cell is not selected as described above.

Description will be made below of the configuration and the operation of the fuse portions L₀ to L₂ₘ₊₁ in the above circuit. FIG. 9 is a schematic top view of the fuse portions.

In the figure, reference numerals 1 to 3 denote fuses and reference numeral 4 denotes an opening. The fuses 1 to 3 are made up of, for example, WSi polycide, aluminum, etc. The opening 4 is formed in a laminated film made up of a plasma SiN film, ployimide, etc.

Conventionally, in fuse portions configured as described above, when a defective cell is found, the corresponding fuse in the circuit is cut off so as to prohibit access to the defective memory cell.

A laser trimming device is used to cut off (blow) the fuse. Specifically, a laser light is irradiated to the center portion of the fuse by use of the laser trimming device. The portion of the fuse to which the laser light has been irradiated expands by heat abruptly and significantly and, as a result, is cut off, setting the fuse in a nonconductive state.

A first problem with the above conventional technique is that the fuse portions are too large to be suitably incorporated in a fine semiconductor device.

Specifically, in the fuse portions shown in FIG. 9, the length of the opening 4 in the latitudinal direction in the figure is approximately 10 μm, and a plurality of fuses 1 are disposed at a pitch of approximately 5 μm. Thus, the fuse portions occupy not a small area in the semiconductor device, obstructing miniaturization of the semiconductor device.

A second problem with the conventional technique is that the fuse cutting-off process has low workability. Specifically, a laser trimming device is required for the process. The preparation of facilities for the fuse cutting-off process and the actual fuse cutting-off process itself necessitate considerable work to be done which cannot be ignored. Furthermore, since a laser light is directly irradiated onto the chip to cut off a fuse, the process cannot be carried out after the chip is packaged. This means that it is not possible to replace defective cells produced in tests, etc. performed after the packaging.

To solve the above problems, there have been proposed semiconductor devices having antifuses instead of fuses therein, as shown in FIG. 10 (for example, see U.S. Pat. No. 4,899,205).

In FIG. 10, reference numeral 11 denotes a silicone substrate; 12a and 12b N₊ diffusion layers each to be used as one electrode; 13 a separating oxide film; 14 and 16 oxide films; 15 a nitride film; 17a and 17b N⁺ type polysilicon to be used as the other electrode; 18 an interlayer insulation film; 19a and 19b connection wires connected to the N⁺ diffusion layers 12a and 12b, respectively; 20a and 20b connection wires connected to the polysilicon 17a and 17b, respectively; and 21 a destroyed portion of the insulation films.

Thus, the antifuse is formed of the oxide film 14, the nitride film 15, and the oxide film 16 collectively constituting a three-layer-structure insulation film which is sandwiched between two electrode pairs, namely the pair of the electrodes 12a and 12b and the pair of the electrodes 17a and 17b. The antifuse is different from the ordinary fuse described above in that the antifuse is nonconductive by default (in a normal state). Specifically, the semiconductor device is controlled such that (normally) a high voltage is not applied between the two electrode pairs (the pair of the electrodes 12a and 12b and the pair of the electrodes 17a and 17b), which is the state of the antifuse on the left in FIG. 10. When it is necessary to set the antifuse to a conductive state, the semiconductor device is controlled such that a high voltage is applied between the two electrode pairs (the pair of the electrodes 12a and 12b and the pair of the electrodes 17a and 17b) to break down the insulation film, which is the state of the antifuse on the right in FIG. 10.

The above device configuration using antifuses can make the size of the device relatively small and its control relatively easy, thereby solving the above-described problems of a semiconductor device having fuse portions therein.

However, in the above device configuration using antifuses, the antifuses must be formed in a process separate from processes in which transistors, capacitors, etc. are formed in the semiconductor device, complicating the process procedure. Specifically, it is necessary to form the N⁺ diffusion layers 12a and 12b and the insulation films 14 to 16 on the N⁺ diffusion layers 12a and 12b in processes separate from the process in which the other elements are formed.

Furthermore, a relatively high voltage is applied to break down the insulation films 14 to 16 to make an antifuse conductive. The application of the relatively high voltage might destroy the gate insulation film for a transistor employed in a circuit for applying the voltage to the antifuse, at that time. If this occurs, the resultant applied voltage is not high enough to break down the insulation films 14 to 16, leaving the antifuse nonconductive.

### SUMMARY OF THE INVENTION

To solve the above problems, it is an object of the present invention to provide a semiconductor device wherein the semiconductor device has antifuses therein which are small and highly reliable and easy to switch between a nonconductive state and a conductive state and which can be fabricated by use of a relatively easy method.

According to one aspect of the present invention, a semiconductor device comprises an antifuse having an insulation film and a breakdown-circuit transistor. The breakdown-circuit transistor is provided in a breakdown circuit for breaking down the insulation film to set the antifuse in a conductive state. The insulation film of the antifuse is made up of a same material as that for a gate insulation film of the breakdown-circuit transistor. The insulation film is formed such that a film thickness of the insulation film is thinner than that of the gate insulation film.

Configured as described above, the present invention can provide a semiconductor device wherein the semiconductor device has antifuses therein which are small and highly reliable and easy to switch between a nonconductive state and a conductive state and which can be fabricated by use of a relatively easy method.

Other and further objects, features and advantages of the invention will appear more fully from the following description.

### BRIEF DESCRIPTION OF THE DRAWINGS

FIG. 1 is a schematic cross-sectional view of a semiconductor device according to the first embodiment of the present invention.

FIG. 2 is a schematic cross-sectional view of the semiconductor device in an ion-implantation process.

FIG. 3 is a schematic cross-sectional view of the semiconductor device in a first oxide film formation process.

FIG. 4 is a schematic cross-sectional view of the semiconductor device in a second oxide film formation process.

FIG. 5 is a circuit diagram showing the semiconductor device of FIG. 1.

FIG. 6 is a schematic cross-sectional view of a semiconductor device according to the second embodiment of the present invention.

FIG. 7 is a circuit diagram showing the semiconductor device of FIG. 6.

FIG. 8 is a circuit diagram showing a replacement circuit for replacing memory cells by use of fuses in the conventional semiconductor device.

FIG. 9 is a schematic diagram showing fuses provided in the replacement circuit shown in FIG. 8.

FIG. 10 is a schematic cross-sectional view of conventional semiconductor devices having antifuses.

### DETAILED DESCRIPTION OF THE PREFERRED EMBODIMENTS

Preferred embodiments of the present invention will be described in detail below with reference to the accompanying drawings. It should be noted that since the same or corresponding components in the figures are denoted by like numerals, their explanation will be simplified or omitted as necessary.

First Embodiment

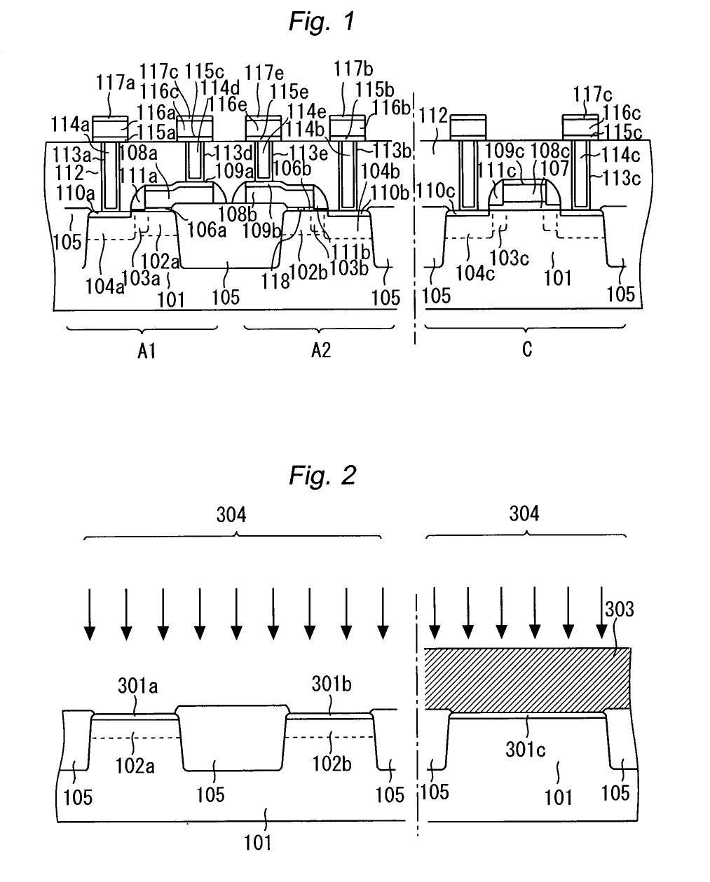

A first embodiment of the present invention will be described in detail with reference to FIGS. 1 to 5. FIG. 1 is a schematic cross-sectional view of a semiconductor device according to the first embodiment of the present invention.

In the figure, reference numeral 101 denotes a silicon substrate having P type wells formed thereon; 102a and 102b N⁺ diffusion layers; 103a and 103b N⁻-implanted N⁻ diffusion layers; 104a to 104c N⁺ diffusion layers having a concentration higher than that of the N⁺ diffusion layers 102a and 102b; 105 a separating oxide film formed using the STI method or the LOCOS method; 106a and 106b oxide films used as insulation films for antifuses; 107 a gate oxide film used as a gate insulation film for a transistor; 108a and 108b N⁺ type polysilicon films used as electrodes for antifuses; 108c N⁺ type polysilicon film used as a gate electrode for the transistor; 109a to 109c silicide films of Co, etc. formed on the polysilicon films 108a to 108c; 110a to 110c silicide films formed on the N⁺ diffusion layers 104a to 104c; 111a to 111c sidewalls made up of oxide films, nitride films, or laminated films thereof; 112 an interlayer insulation film made up of an oxide film; 113a to 113e barrier metal of TiN formed on contact holes in the interlayer insulation film 112; 114a to 114e W plugs formed on the contact holes in the interlayer film 112; 115a to 115e barrier metal of upper layer wires; 116a to 116e aluminum layers of the upper layer wires; 117a to 117e antireflective films of TiN for the upper layer wires; and 118 a destroyed portion indicating a portion whose insulation has been broken down in the oxide film 106b.

Areas A1 and A2 in FIG. 1 function as antifuses. It should be noted that the antifuse A1 is in a nonconductive state and used as an element through which no current flows, whereas the antifuse A2 is in a conductive state and used as an element through which a current flows. Furthermore, an area C functions as a transistor (a breakdown-circuit transistor) included in a breakdown circuit for breaking down the oxide films 106a and 106b for the antifuses A1 and A2.

The oxide films 106a and 106b for antifuses A1 and A2 are made up of the same materials as those for the gate oxide film 107 for the transistor C, and are formed such that their film thickness is thinner than that of the gate oxide film 107. With this configuration, when a voltage is applied to the above breakdown circuit to break down the oxide films 106a and 106b for the antifuses A1 and A2, the withstand voltage characteristic of the transistor C in the circuit can be kept high enough so that the transistor C does not break down.

For example, assume that the film thickness of the oxide films 106a and 106b for the antifuses A1 and A2 is approximately 3 nm, and the film thickness of the gate oxide film 107 for the transistor C is 6 to 8 nm or more. With this arrangement, the withstand voltage of the antifuses A1 and A2 against breakdown is approximately 4V, while the withstand voltage of the transistor C is 7V or more.

In a semiconductor device configured as described above, the antifuses can be formed such that their area is relatively small such as approximately 2 μm×2 μm. Furthermore, the process for breaking down the antifuse does not require a laser trimming device described above, reducing the process time and the production cost.

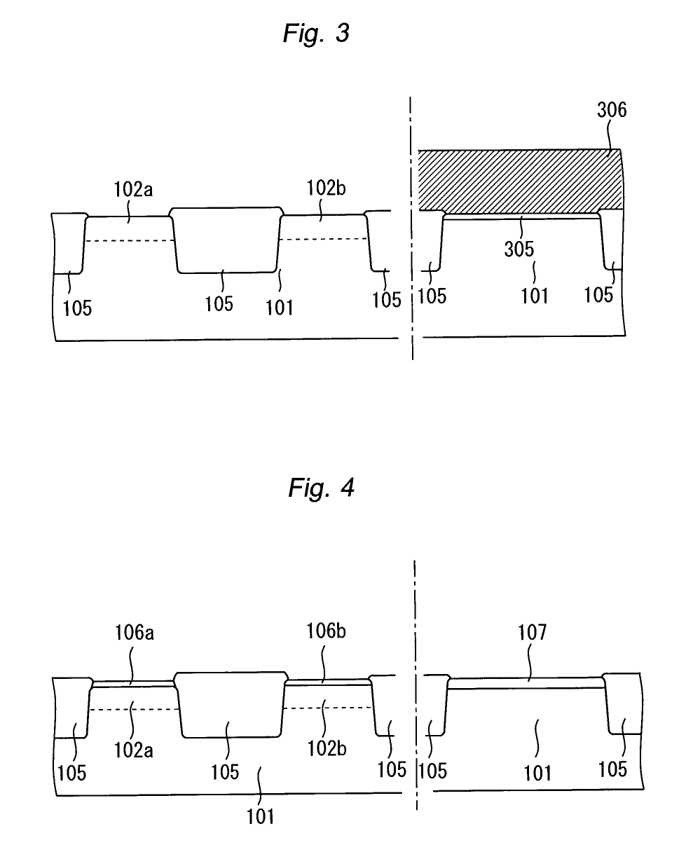

Description will be made below of a method for fabricating a semiconductor device configured as described above with reference to FIGS. 2 to 4. FIG. 2 is a schematic cross-sectional view of the semiconductor device in an ion-implantation process; FIG. 3 is a schematic cross-sectional view of the semiconductor device in a first oxide film formation process; and FIG. 4 is a schematic cross-sectional view of the semiconductor device in a second oxide film formation process.

In the figures, reference numerals 102a and 102b denote the N⁺ diffusion layers; 106a and 106b the thin oxide films for the antifuses; 107 the thick gate oxide film for the transistor; 301a to 301c sacrificial oxide films; 303 and 306 resist films; 304 ions; and 305 a gate oxide film formed in the first oxide film formation process.

It should be noted that the area to the right of the chain line in each figure corresponds to the transistor C in FIG. 1 whereas the area to the left of the chain line in each figure corresponds to the antifuses A1 and A2.

Initially, the separating oxide film 105 is formed on the silicon substrate 101 using the STI method or the LOCOS method. Then, B ions are implanted from over the sacrificial oxide films 301a to 301c which were formed together with the separating oxide film 105 so as to form P type wells on the silicon substrate 101.

After that, the N⁺ diffusion layers 102a and 102b each to be used as one electrode of a respective antifuse are formed in the antifuse area, as shown in FIG. 2. It should be noted that in this process a diffusion layer(s) for a MOS capacitor(s) is also formed in the semiconductor device at the same time.

Specifically, to expose only the areas for the antifuse electrode portions and the MOS capacitor electrode (diffusion layer) portions in the semiconductor device, the resist film 303 is formed so as to prevent ion-implantation into the other areas. In FIG. 2, the resist film 303 is formed on the sacrificial oxide film 301c and the separating oxide film 105 in the transistor area.

Then, the ions 304 are implanted. For example, the ions 304 are of P or As and implanted under the condition of an acceleration energy of 80 keV, and a dose of 1×10¹⁵ ions/cm².

This implantation forms the N⁺ diffusion layers 102a and 102b in the antifuse area as electrode portions as well as forming an N⁺ diffusion layer in the MOS capacitor area (not shown).

Afterwards, the resist film 303 is removed, and furthermore the sacrificial oxide films 301a to 301c are also removed by use of hydrofluoric acid.

Then, as shown in FIGS. 3 and 4, the dual oxide film formation process (that is, the first and second oxide film formation processes combined) is carried out to form a thin oxide film in the antifuse area and a thick gate oxide film in the transistor area. It should be noted that this process also forms the thin and thick gate oxide films for the other transistors in the semiconductor device at the same time.

Specifically, the first oxide film formation process forms an oxide film on the top surface of the substrate to a film thickness of approximately 5 to 7 nm. After that, the resist film 306 is formed in the transistor area in which the thick gate oxide film is to be formed. In FIG. 3, the resist film 306 covers the gate oxide film 305 for the transistor for the breakdown circuit.

Then, oxide films other than those in the transistor area in which the thick gate oxide film is to be formed are removed by use of hydrofluoric acid after the photolithography. FIG. 3 shows the antifuse area after its oxide films have been removed.

After the resist film 306 is removed, the second oxide film formation process forms the thin oxide films 106a and 106b in the antifuse area to a film thickness of approximately 2 to 3 nm as well as forming the thick gate oxide film 107 in the transistor area. It should be noted that the gate oxide film (gate oxide film 107) in the transistor area obtained in the second oxide film formation process is produced as a result of increasing the thickness of the gate oxide film 305 formed in the above first oxide film formation process. The resultant gate oxide film 107 has a film thickness of approximately 6 to 8 nm.

As for transistor areas (not shown) other than the antifuse area and the area for the transistor for the breakdown circuit, thin and thick gate oxide films are formed in them in the above dual oxide film formation process.

Subsequently, the polysilicon films 108a and 108b used as electrodes for the antifuses and the polysilicon film 108c used as the gate electrode for the transistor are formed at the same time. After that, the following components are sequentially formed: the silicide films 109a to 109c and 110a to 110c; the interlayer insulation film 112; contact holes; the barrier metal film 113a to 113e; the W plugs 114a to 114e; the upper layer wires 115a to 115e, 116a to 116e, and 117a to 117e.

According to the first embodiment described above, a relatively easy semiconductor fabrication method can be realized since antifuses and a transistor for a breakdown circuit can be fabricated at the same time with thin and thick film transistors used in logic semiconductor devices, etc. or MOS capacitors used in analog circuits, etc.

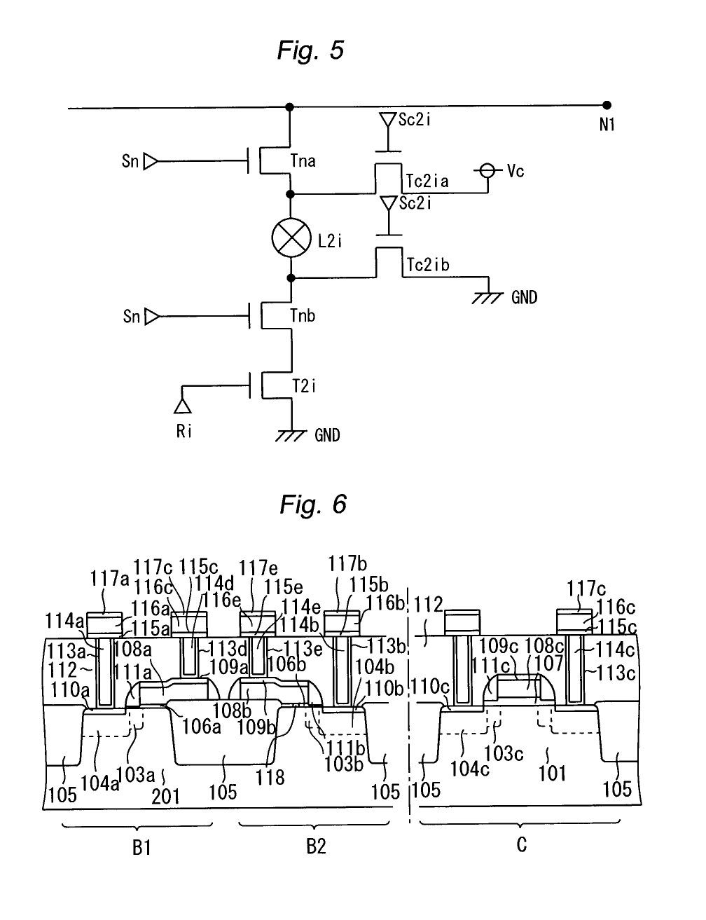

Description will be made below of a breakdown circuit having antifuses and a transistor for the breakdown circuit therein and a control method for the breakdown circuit with reference to FIG. 5. FIG. 5 is a circuit diagram showing the semiconductor device of FIG. 1. Specifically, FIG. 5 shows a portion of the replacement circuit for replacing defective cells described earlier. The present replacement circuit is obtained as a result of replacing the portion of the replacement circuit in FIG. 8 which branches from the node N1 by the circuit shown in FIG. 5.

In the figure, reference numeral Vc denotes a potential for breakdown; L₂ᵢ an antifuse portion including an antifuse; T_{c2ia} and T_{c2ib} transistors for a breakdown circuit having a thick oxide film; S_{c2i} a breakdown signal for programming antifuses; Rᵢ an address signal; T₂ᵢ a thin- or thick-film transistor corresponding to the address signal Rᵢ; Sₙ an operation signal for indicating an ordinary operation; and Tₙₐ and T_{nb} thin- or thick-film transistors each corresponding to the operation signal Sₙ.

In a semiconductor device circuit configured as described above, when it is necessary to program the antifuses, the operation signal Sₙ is set at a low level, turning off the transistors Tₙₐ and T_{nb}.

In this state, when programming the antifuse portion L₂ᵢ such that it is in a nonconductive state, the breakdown signal S_{c2i} is set at a low level. At that time, the transistors T_{c2ia} and T_{c2ib} for the breakdown circuit are turned off and as a result the breakdown potential Vc is not applied to the antifuse portion L₂ᵢ, keeping the antifuse portion L₂ᵢ in the nonconductive state.

When programming the antifuse portion L₂ᵢ such that it is in a conductive state, on the other hand, the breakdown signal Sc₂ᵢ is set at a high level. At that time, the transistors T_{c2ia} and T_{c2ib} for the breakdown circuit are turned on and as a result the breakdown potential Vc is applied to the antifuse portion L₂ᵢ, destroying the oxide film of the antifuse portion L₂ᵢ and thereby switching the antifuse portion L₂ᵢ to the conductive state.

In an ordinary operation, the breakdown signal S_{c2i} is set at a low level and the operation signal Sₙ is set at a high level, turning on the transistors Tₙₐ and T_{nb}. In this state, the potential of the node N1 is controlled such that it is grounded or not grounded by using the address signal Rᵢ and setting the antifuse portion L₂ᵢ in a conductive or nonconductive state.

Thus, the present replacement circuit replaces defective cells with redundant cells as does the replacement circuit shown in FIG. 8 described earlier.

As described above, the antifuse portion L₂ᵢ is included in (belongs to) both the breakdown circuit having the transistors T_{c2ia} and T_{c2ib} for the breakdown circuit and the replacement circuit having other transistors Tₙₐ, T_{nb}, and T₂ᵢ, at the same time.

With such an arrangement, the following control is performed by use of a program. First, the voltage Vc is applied to the breakdown circuit though the transistors T_{c2ia} and T_{c2ib} for the breakdown circuit to destroy the insulation film of the antifuse portion L₂ᵢ. Then, the breakdown circuit is opened and the replacement circuit is closed.

As described above, the first embodiment provides a semiconductor device and a control method and a fabrication method for the semiconductor device wherein the semiconductor device has antifuses therein which are small and highly reliable and easy to switch between a nonconductive state and a conductive state and which can be fabricated by use of a relatively easy method.

It should be noted that the first embodiment forms P type wells on the silicon substrate 101, and N type diffusion layers 102a, 102b, 103a, 103b, 104a, and 104b, to be used as electrodes, under the oxide films 106a and 106b for the antifuses A1 and A2. However, the present invention may be configured such that: N type wells are formed on the silicon substrate 101; P⁺ type diffusion layers are formed under the oxide films 106a and 106b for the antifuses A1 and A2 as electrodes; and P⁺ polysilicon layers are formed on the oxide films 106a and 106b also as electrodes. This arrangement also produces the effects of the first embodiment described above.

Further, even though the first embodiment uses an NMOS transistor as the transistor C, a PMOS transistor may be used instead.

Further, even though the first embodiment uses the oxide films 106a, 106b, and 107 as the insulation films for the antifuses and the gate insulation film for the transistor, nitride films may be used as the insulation films for the antifuses and the gate insulation film for the transistor, instead.

Further, even though the first embodiment uses the polysilicon films 108a to 108c and the silicide films 109a to 109c formed on the polysilicon films 108a to 108c as the antifuse electrode portions and the gate electrode for the transistor, the structure of the antifuse electrode portions and the transistor gate electrode is not limited to this specific arrangement. For example, it is possible to employ a laminated electrode structure including N⁺ doped polysilicon and WSi silicide, or a “poly metal” structure of ion-implanted polysilicon having W metal laminated thereon.

Further, the first embodiment forms the silicide films 110a and 110b over the N⁺ diffusion layers 104a and 104b. However, even when the silicide films 110a and 110b are not formed, the N type diffusion layers 102a, 102b, 103a, 103b, 104a, and 104b each function as one electrode of an antifuse.

Further, the first embodiment uses the W plugs 114a to 114e as the contact portions and the aluminum layers 116a to 116e as upper layer wires. However, the contact portions and the upper layer wires are not limited to these specific materials. For example, copper plugs and copper wiring, etc. may be employed using the dual damascene method.

Further, even though the first embodiment applies the antifuses A1 and A2 and the transistor C to a circuit for replacing defective cells, the present invention is not limited to this specific application. The present invention can be applied to other circuits, for example, a reference voltage generation circuit for generating a reference voltage.

Second Embodiment

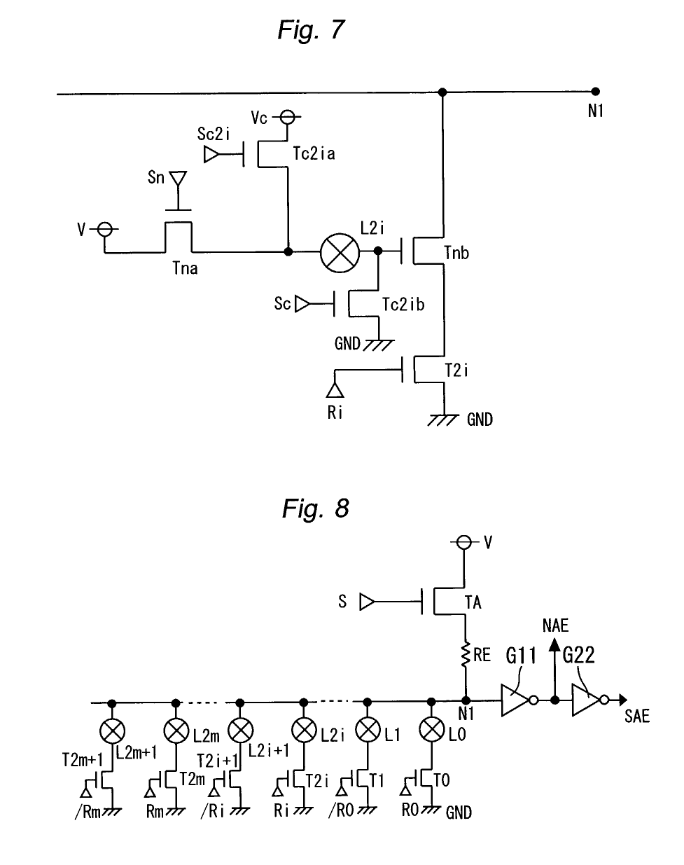

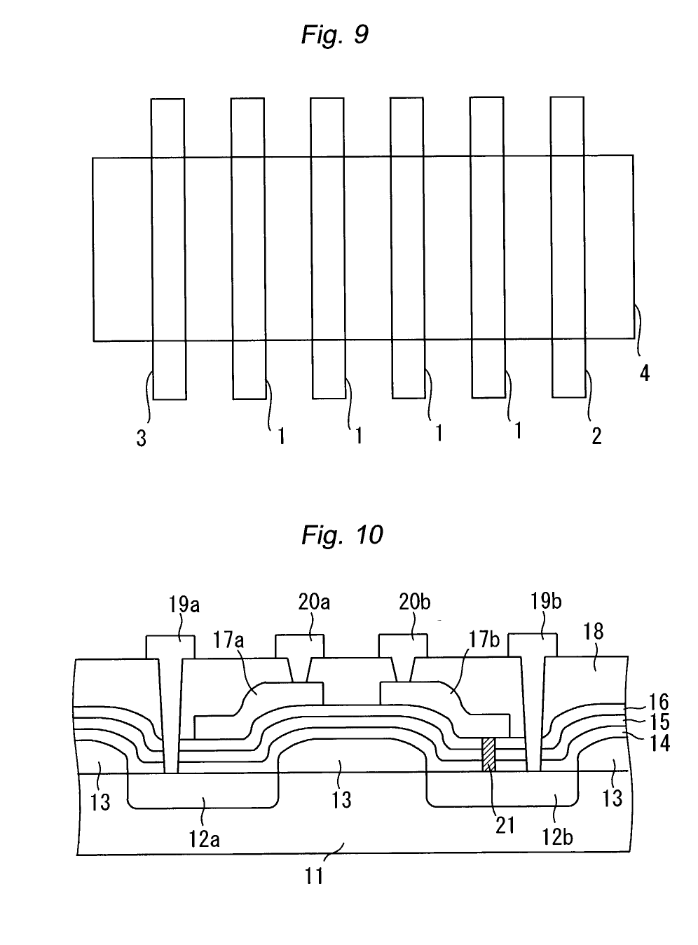

A second embodiment of the present invention will be described in detail with reference to FIGS. 6 and 7. FIG. 6 is a schematic cross-sectional view of a semiconductor device according to the second embodiment of the present invention.

The second embodiment is different from the above first embodiment in that the N+diffusion layers 102a and 102b are not formed under the oxide films 106a and 106b for the antifuses and furthermore N type wells are formed on the silicon substrate under the antifuses in the second embodiment.

Referring to FIG. 6, reference numerals 103a to 103c denote N⁻ diffusion layers; 104a to 104c N⁺ diffusion layers; and 201 a silicon substrate on which N type wells are formed.

Areas B1 and B2 in FIG. 6 function as antifuses. It should be noted that the antifuse B1 is in a nonconductive state and used as an element through which no current flows, whereas the antifuse B2 is in a conductive state and used as an element through which a current flows. Furthermore, an area C functions as a transistor included in a breakdown circuit for breaking down the oxide films 106a and 106b for the antifuses B1 and B2.

The oxide films 106a and 106b for the antifuses B1 and B2 are made up of the same materials as those for the gate oxide film 107 for the transistor C, and are formed such that their film thickness is thinner than that of the gate oxide film 107, as is the case with the above first embodiment.

In the antifuse B2 in the conductive state, a current flows through the N⁺ diffusion layer 104b, the N⁻ diffusion layer 103b, the N type silicon substrate 201, the destroyed portion 118, and the polysilicon film 108b in that order.

Description will be made below of a method for fabricating a semiconductor device configured as described above.

Initially, the separating oxide film 105 is formed on the silicon substrate 101. Then, on the transistor C side, B ions are implanted from over the sacrificial oxide films which were formed together with the separating oxide film 105 to produce the silicon substrate 101 on which P type wells are formed. On the antifuse side (the antifuses A1 and A2), P ions are implanted to produce the silicon substrate 201 on which N type wells are formed.

Then, the N⁻ diffusion layers 103a to 103c and the N⁺ diffusion layers 104a to 104c are formed in the antifuses B1 and B2 and the transistor C as in the case of the above first embodiment.

Also as in the case of the above first embodiment, a dual oxide film formation process forms a thin oxide film in the antifuse area and a thick gate oxide film in the transistor area.

Subsequently, the polysilicon films 108a and 108b used as the electrodes for the antifuses and the polysilicon film 108c used as the gate electrode for the transistor are formed at the same time. After that, the following components are sequentially formed: the silicide films 109a to 109c and 110a to 110c; the interlayer insulation film 112, contact holes; the barrier metal film 113a to 113e; the W plugs 114a to 114e; the upper layer wires 115a to 115e, 116a to 116e, and 117a to 117e.

Description will be made below of a breakdown circuit having antifuses and a transistor for the breakdown circuit therein and a control method for the breakdown circuit with reference to FIG. 7. FIG. 7 is a circuit diagram showing the semiconductor device of FIG. 6. Specifically, FIG. 7 shows a portion of a replacement circuit for replacing defective cells described earlier as described in the first embodiment.

Referring to FIG. 7, reference numeral V denotes a source potential; Vc a potential for breakdown; L₂ᵢ an antifuse portion; T_{c2ia} and T_{c2ib} transistors for a breakdown circuit having a thick oxide film; S_{c2i} a breakdown signal; Rᵢ an address signal; T₂ᵢ a transistor corresponding to the address signal Rᵢ; Sₙ an operation signal; and Tₙₐ and T_{nb} transistors each corresponding to the operation signal Sₙ.

In a semiconductor device circuit configured as described above, when it is necessary to program the antifuses, the operation signal Sₙ is set at a low level, turning off the transistors Tₙₐ and T_{nb}.

In this state, when programming the antifuse portion L₂ᵢ such that it is in a nonconductive state, the breakdown signal S_{c2i} is set at a low level. At that time, the transistors T_{c2ia} and T_{c2ib} for the breakdown circuit are turned off and as a result the breakdown potential Vc is not applied to the antifuse portion L₂ᵢ, keeping the antifuse portion L₂ᵢ in the nonconductive state.

When programming the antifuse portion L₂ᵢ such that it is in a conductive state, on the other hand, the breakdown signal S_{c2i} is set at a high level. At that time, the transistors T_{c2ia} and T_{c2ib} for the breakdown circuit are turned on and as a result the breakdown potential Vc is applied to the antifuse portion L₂ᵢ, destroying the oxide film of the antifuse portion L₂ᵢ and thereby switching the antifuse portion L₂ᵢ to the conductive state.

In an ordinary operation, the breakdown signal S_{c2i} is set at a low level and the operation signal Sₙ is set at a high level, turning on the transistors Tₙₐ. The transistor T_{nb}, on the other hand, is turned on or off by setting the antifuse portion L₂ᵢ in a conductive or nonconductive state. The potential of the node N1 is controlled such that it is grounded or not grounded by using the address signal Rᵢ and turning on or of f the transistor T_{nb}.

Thus, the present replacement circuit replaces defective cells with redundant cells as does the replacement circuit shown in FIG. 8 described earlier.

According to the second embodiment described above, the antifuse portion L₂ᵢ provided in the breakdown circuit is also included in another circuit whose potential is fixed after the oxide film of the antifuse has been broken down, making it possible to use an element having a relatively high resistance as the antifuse portion L₂ᵢ.

That is, after the oxide film of the antifuse portion L₂ᵢ has been destroyed, no current flows from the node N1 to the antifuse portion L₂ᵢ even if the address signal Rᵢ is entered. Therefore, it is possible to ensure stable operation of the replacement circuit even when the silicon substrate 201 having N type wells is provided under the oxide films 106a and 106b, that is, even in a configuration employing antifuses having a relatively high resistance.

Thus, the second embodiment provides, as does the first embodiment, a semiconductor device and a control method and a fabrication method for the semiconductor device wherein the semiconductor device has antifuses therein which are small and highly reliable and easy to switch between a nonconductive state and a conductive state and which can be fabricated by use of a relatively easy method.

It should be noted that the present invention is not limited to each preferred embodiment thereof described above. Rather, it is clear that each embodiment can be altered within the scope of the technical idea of the present invention as necessary. Furthermore, the number, the positions, and the shapes of the components employed by the present invention are also not limited to each embodiment described above. Any number, positions, and shapes of components can be employed if they are suitable for implementing the present invention.

Configured as described above, the present invention can provide a semiconductor device and a control method and a fabrication method for the semiconductor device wherein the semiconductor device has antifuses therein which are small and highly reliable and easy to switch between a nonconductive state and a conductive state and which can be fabricated by use of a relatively easy method.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-364919, filed on Nov. 29, 2001 including specification, claims, drawings and summary, on which the Convention priority of the present application is based, are incorporated herein by reference in its entirety.

1. A semiconductor device comprising:
an antifuse having an insulation film; and
a breakdown-circuit transistor provided in a breakdown circuit for breaking down said insulation film to set said antifuse in a conductive state;
wherein said insulation film of said antifuse is made up of a same material as that for a gate insulation film of said breakdown-circuit transistor and formed such that a film thickness of said insulation film is thinner than that of said gate insulation film.

2. The semiconductor device according to claim 1, wherein an N⁺ diffusion layer or a P⁺ diffusion layer is provided under said insulation film of said antifuse.

3. The semiconductor device according to claim 1, wherein said antifuse has an electrode made up of a same material as that for a gate electrode of said breakdown-circuit transistor.

4. The semiconductor device according to claim 1, wherein said antifuse is included in both said breakdown circuit and another circuit, said another circuit having a transistor different from said breakdown-circuit transistor.

5. The semiconductor device according to claim 1, wherein said antifuse is included in both said breakdown circuit and another circuit whose potential is fixed after said insulation film has been broken down.
